(19) United States
(12) Patent Application Publication
(10) Pub. No.: US 2026/0271315 A1
(43) Pub. Date: Sep. 10, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Takato YAMAMOTO, Kawasaki Kanagawa (JP); Yusuke KOBAYASHI, Yokohama Kanagawa (JP); Teruyuki OHASHI, Kawasaki Kanagawa (JP); Tomoko MATSUDAI, Shibuya Tokyo (JP); Kota KATO, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/448,186

(22) Filed: Jan. 14, 2026

(30) Foreign Application Priority Data
Mar. 5, 2025 (JP) 2025-034959

(51) Int. Cl. H10D 12/00

(52) U.S. Cl. CPC H10D 12/416; H10D 12/481

(57) ABSTRACT

According to one embodiment, a semiconductor device includes first to fourth electrodes, a semiconductor member, and first and second insulating members. At least a part of the second insulating member is between the fourth electrode and the first semiconductor portion, between the fourth electrode and the second partial region, and between the fourth electrode and the fourth semiconductor region. The first electrode is electrically connected to the fifth semiconductor region. A fourth impurity concentration of the first conductivity type in at least a part of the fourth semiconductor region is higher than a first impurity concentration of the first conductivity type in the first semiconductor region.

### CROSS-REFERENCE TO RELATED APPLICATIONS

This application is based upon and claims the benefit of priority from Japanese Patent Application No. 2025-034959, filed on Mar. 5, 2025; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIG. 1 is a schematic cross-sectional view illustrating a semiconductor device according to a first embodiment;

FIG. 2 is a graph illustrating the semiconductor device according to the first embodiment;

FIG. 3 is a schematic transparent plan view illustrating the semiconductor device according to the first embodiment;

FIG. 4 is a schematic transparent plan view illustrating a semiconductor device according to the first embodiment;

FIG. 5 is a schematic transmission plane view illustrating a semiconductor device according to the first embodiment;

FIG. 6 is a schematic transmission plane view illustrating a semiconductor device according to the first embodiment;

FIG. 7 is a schematic cross-sectional view illustrating a semiconductor device according to the first embodiment;

FIG. 8 is a schematic transparent plan view illustrating the semiconductor device according to the first embodiment;

FIG. 9 is a schematic transparent plan view illustrating a semiconductor device according to the first embodiment;

FIG. 10 is a schematic cross-sectional view illustrating a semiconductor device according to the first embodiment;

FIG. 11 is a schematic transparent plane view illustrating the semiconductor device according to the first embodiment;

FIG. 12 is a schematic transparent plane view illustrating a semiconductor device according to the first embodiment;

FIG. 13 is a schematic cross-sectional view illustrating a semiconductor device according to the first embodiment;

FIG. 14 is a schematic cross-sectional view illustrating a semiconductor device according to a second embodiment;

FIG. 15 is a schematic cross-sectional view illustrating a semiconductor device according to the second embodiment;

FIG. 16 is a schematic transparent plan view illustrating the semiconductor device according to the second embodiment; and

FIG. 17 is a schematic transparent plan view illustrating a semiconductor device according to the second embodiment.

### DETAILED DESCRIPTION

According to one embodiment, a semiconductor device includes a first electrode, a second electrode, a third electrode, a fourth electrode, a semiconductor member, a first insulating member, and a second insulating member. At least a part of the semiconductor member is between the first electrode and the second electrode in a first direction from the first electrode to the second electrode. The semiconductor member includes a first semiconductor region of a first conductivity type, a second semiconductor region of a second conductivity type, a third semiconductor region of the first conductivity type, a fourth semiconductor region of the first conductivity type, a fifth semiconductor region of the second conductivity type, and a sixth semiconductor region of the first conductivity type. The second electrode is electrically connected to the third semiconductor region. At least a part of the second semiconductor region is between the first semiconductor region and the third semiconductor region. At least a part of the first insulating member is between the third electrode and the first semiconductor region, between the third electrode and the second semiconductor region, and between the third electrode and the third semiconductor region. The fifth semiconductor region includes a first partial region, a second partial region, a third partial region, and a fourth partial region. The fourth semiconductor region is between the second partial region and the fourth partial region in a second direction crossing the first direction. The sixth semiconductor region includes a first semiconductor portion. The first semiconductor portion is between the third partial region and the fourth semiconductor region in the second direction. The second partial region is between the first semiconductor portion and the fourth semiconductor region. A part of the first semiconductor portion is between the first electrode and the first partial region in the first direction. The fourth partial region is between the first electrode and the first semiconductor region in the first direction. At least a part of the second insulating member is between the fourth electrode and the first semiconductor portion, between the fourth electrode and the second partial region, and between the fourth electrode and the fourth semiconductor region. The first electrode is electrically connected to the fifth semiconductor region. A fourth impurity concentration of the first conductivity type in at least a part of the fourth semiconductor region is higher than a first impurity concentration of the first conductivity type in the first semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

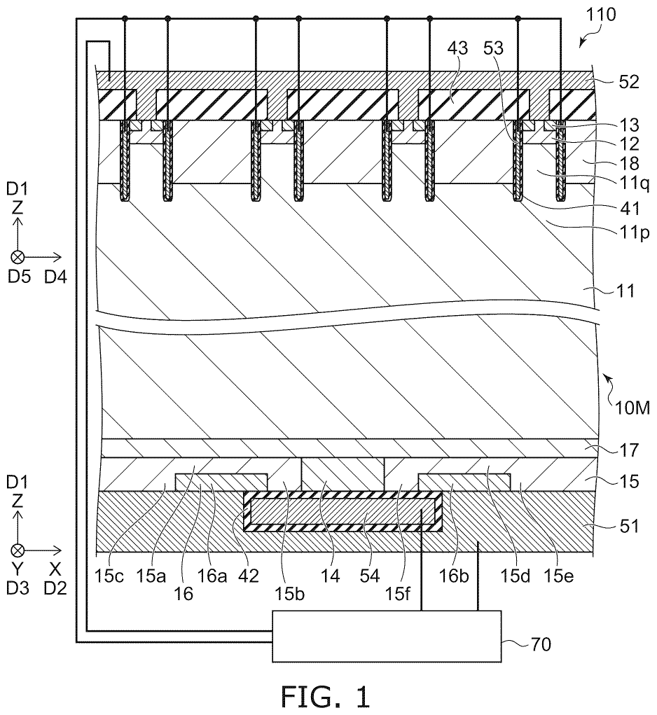

FIG. 1 is a schematic cross-sectional view illustrating a semiconductor device according to the first embodiment.

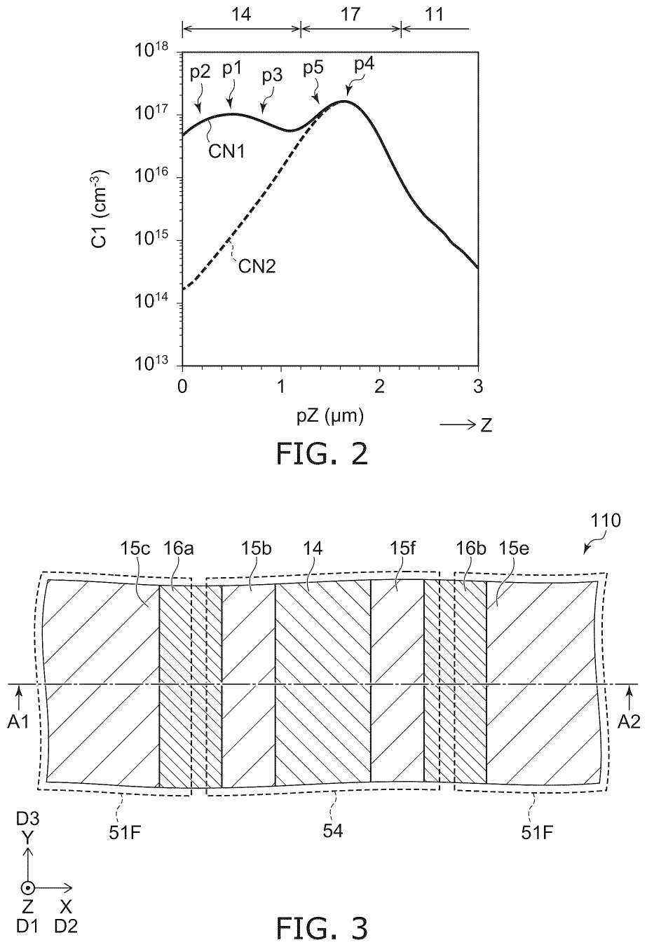

FIG. 2 is a graph illustrating the semiconductor device according to the first embodiment.

FIG. 3 is a schematic transparent plan view illustrating the semiconductor device according to the first embodiment.

FIG. 1 corresponds to a cross-sectional view taken along the line A1-A2 in FIG. 3.

As shown in FIG. 1, a semiconductor device 110 according to the embodiment includes a first electrode 51, a second electrode 52, a third electrode 53, a fourth electrode 54, a semiconductor member 10M, a first insulating member 41 and a second insulating member 42.

At least a part of the semiconductor member 10M is between the first electrode 51 and the second electrode 52 in a first direction D1 from the first electrode 51 to the second electrode 52.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The semiconductor member 10M includes a first semiconductor region 11 of a first conductivity type, a second semiconductor region 12 of a second conductivity type, a third semiconductor region 13 of the first conductivity type, a fourth semiconductor region 14 of the first conductivity type, a fifth semiconductor region 15 of the second conductivity type, and a sixth semiconductor region 16 of the first conductivity type. The first conductivity type is one of n-type and p-type. The second conductivity type is the other of n-type and p-type. In the following, the first conductivity type is n-type, and the second conductivity type is p-type.

The second electrode 52 is electrically connected to the third semiconductor region 13. At least a part of the second semiconductor region 12 is provided between the first semiconductor region 11 and the third semiconductor region 13. At least a part of the first insulating member 41 is provided between the third electrode 53 and a part of the first semiconductor region 11, between the third electrode 53 and the second semiconductor region 12, and between the third electrode 53 and the third semiconductor region 13. At least a part of the third electrode 53 faces a part of the first semiconductor region 11, the second semiconductor region 12, and the third semiconductor region 13.

The fifth semiconductor region 15 includes a first partial region 15a, a second partial region 15b, a third partial region 15c, and a fourth partial region 15d. The fifth semiconductor region 15 may further include other partial regions (for example, a fifth partial region 15e, etc.). The boundaries between these partial regions may be clear or unclear.

The fourth semiconductor region 14 is located between the second partial region 15b and the fourth partial region 15d in a second direction D2 that crosses the first direction D1.

The sixth semiconductor region 16 includes a first semiconductor portion 16a. The first semiconductor portion 16a is provided between the third partial region 15c and the fourth semiconductor region 14 in the second direction D2. The second partial region 15b is provided between the first semiconductor portion 16a and the fourth semiconductor region 14 in the second direction D2.

A part of the first semiconductor portion 16a is between the first electrode 51 and the first partial region 15a in the first direction D1. For example, another part of the first semiconductor portion 16a may be between the fourth electrode 54 and the first partial region 15a in the first direction D1.

The fourth partial region 15d is between the first electrode 51 and the first semiconductor region 11 in the first direction D1. In this example, a part of the fourth partial region 15d is located between the fifth partial region 15e and the first semiconductor region 11 in the first direction D1.

At least a part of the second insulating member 42 is between the fourth electrode 54 and the first semiconductor portion 16a, between the fourth electrode 54 and the second partial region 15b, and between the fourth electrode 54 and the fourth semiconductor region 14. The first electrode 51 is electrically connected to the fifth semiconductor region 15. For example, the first electrode 51 is electrically connected to the third partial region 15c, the fourth partial region 15d, and the fifth partial region 15e. The first electrode 51 may be in contact with the third partial region 15c, the fourth partial region 15d, and the fifth partial region 15e.

Current flowing between the first electrode 51 and the second electrode 52 can be controlled by a potential of the third electrode 53. The first electrode 51 functions as a collector electrode. The second electrode 52 functions as an emitter electrode. The third electrode 53 functions as a gate electrode. The semiconductor device 110 is, for example, an IGBT (Insulated Gate Bipolar Transistor).

The semiconductor device 110 includes the fourth electrode 54 described above. A part of the fourth electrode 54 faces the sixth semiconductor region 16 of the first conductivity type and a part of the fifth semiconductor region 15 of the second conductivity type. For example, a part of the fourth electrode 54 may face the fourth semiconductor region 14 of the first conductivity type. By controlling a potential of the fourth electrode 54, for example, it is possible to control the charge (e.g., holes) injected from the first electrode 51. For example, it is possible to control the charge (e.g., holes) injected from the fifth semiconductor region 15 toward the seventh semiconductor region 17 described below.

The potentials of these electrodes may be controlled by the controller 70. The semiconductor device 110 may include the controller 70.

In FIG. 1, a current path including the first semiconductor portion 16a, the second partial region 15b, and the fourth semiconductor region 14 can be controlled by the potential of the fourth electrode 54. For example, when the potential of the fourth electrode 54 exceeds a threshold value, a current path is formed in the part of the second partial region 15b facing the fourth electrode 54. By controlling the potential of the fourth electrode 54, the current path is opened and closed. For example, when the current path is open, electrons can move from the fourth semiconductor region 14 toward the first electrode 51 via the second partial region 15b and the first semiconductor portion 16a. For example, electrons are discharged toward the first electrode 51.

In the embodiment, a fourth impurity concentration C14 of the first conductivity type in at least a part of the fourth semiconductor region 14 is higher than a first impurity concentration C11 of the first conductivity type in the first semiconductor region 11. For example, in an open state of a current path including the first semiconductor portion 16a, the second partial region 15b, and the fourth semiconductor region 14, the electrical resistance of the fourth semiconductor region 14 becomes low. For example, electrons can move from the fourth semiconductor region 14 toward the first electrode 51 via the second partial region 15b and the first semiconductor portion 16a.

In the embodiment, efficient discharge of electrons and suppression of hole injection are effectively implemented. For example, turn-off loss is effectively suppressed. According to the embodiment, a semiconductor device capable of improving characteristics is provided.

For example, in a first reference example, the fourth impurity concentration C14 of the first conductivity type in the fourth semiconductor region 14 is not higher than the first impurity concentration C11 of the first conductivity type in the first semiconductor region 11. For example, in the open state of the current path including the first semiconductor portion 16a, the second partial region 15b, and the fourth semiconductor region 14, the electrical resistance of the fourth semiconductor region 14 becomes high. For example, electrons cannot move sufficiently from the fourth semiconductor region 14 toward the first electrode 51 via the second partial region 15b and the first semiconductor portion 16a. For example, the turn-off loss is large.

FIG. 2 is a graph illustrating a semiconductor device according to the first embodiment.

In FIG. 2, the horizontal axis is position pZ in the Z-axis direction. The Z-axis direction is along the first direction D1. The vertical axis in FIG. 2 is the impurity concentration C1 of the first conductivity type. The first characteristic CN1 corresponds the semiconductor device 110. The second characteristic CN2 corresponds the first reference example.

As shown in FIG. 2, the fourth semiconductor region 14 includes a first position p1, a second position p2, and a third position p3. The second position p2 is between the fourth electrode 54 and the first position p1 in the first direction D1. The first position p1 is between the second position p2 and the third position p3 in the first direction D1.

The fourth impurity concentration C14 of the first conductivity type in at least a part of the fourth semiconductor region 14 is higher than the first impurity concentration C11 of the first conductivity type in the first semiconductor region 11. A second position impurity concentration Cp2 of the first conductivity type at the second position p2 is lower than the first position impurity concentration Cp1 of the first conductivity type at the first position p1. A third position impurity concentration Cp3 of the first conductivity type at the third position p3 is lower than the first position impurity concentration Cp1.

The semiconductor member 10M may further include a seventh semiconductor region 17 of the first conductivity type. At least a part of the seventh semiconductor region 17 is between the fifth semiconductor region 15 and the first semiconductor region 11, and between the fourth semiconductor region 14 and the first semiconductor region 11 in the first direction D1. A seventh impurity concentration C17 of the first conductivity type in the seventh semiconductor region 17 is higher than the first impurity concentration C11.

As shown in FIG. 2, the seventh semiconductor region 17 includes a fourth position p4 and a fifth position p5. The fifth position p5 is between the third position p3 and the fourth position p4 in the first direction D1.

A fifth position impurity concentration Cp5 of the first conductivity type at the fifth position p5 is lower than a fourth position impurity concentration Cp4 of the first conductivity type at the fourth position p4. For example, the fourth position impurity concentration Cp4 is higher than the first impurity concentration C11.

In the embodiment, the first position impurity concentration Cp1 is, for example, not less than 1×10¹⁴ cm⁻³ and not more than 1×10²¹ cm⁻³. The fourth position impurity concentration Cp4 is, for example, not less than 1×10¹⁴ cm⁻³ and not more than 1×10²¹ cm⁻³. The first impurity concentration C11 is, for example, not less than 1×10¹⁴ cm⁻³ and not more than 1×10²¹ cm⁻³.

As shown in FIG. 1, in this example, a direction from the third electrode 53 to the second semiconductor region 12 is along a fourth direction D4 that crosses the first direction D1. A direction from the third electrode 53 to the third semiconductor region 13 is along the fourth direction D4.

The fourth direction D4 may be along the second direction D2. The fourth direction D4 may cross the second direction D2. The angle between the fourth direction D4 and the second direction D2 is arbitrary.

As shown in FIG. 1, in this example, a direction from the part 11p of the first semiconductor region 11 to the third electrode 53 is along the first direction D1. A direction from the third electrode 53 to another part 11q of the first semiconductor region 11 is along the fourth direction D4. In this example, the third electrode 53 is a trench gate. The third electrode 53 may extend along a fifth direction D5. The fifth direction D5 crosses plane including the first direction D1 and the fourth direction D4.

In this example, the semiconductor member 10M includes an eighth semiconductor region 18 of the second conductivity type. In the fourth direction D4, the third electrode 53 may be provided between the eighth semiconductor region 18 and the second semiconductor region 12.

In the embodiment, the direction from the third semiconductor region 13 to the third electrode 53 may be along the first direction D1.

A plurality of third electrodes 53 may be provided. The plurality of third electrodes 53 are arranged along the fourth direction D4.

In the embodiment, a plurality of fourth electrodes 54 may be provided. The plurality of fourth electrodes 54 extend in the fifth direction D5. The plurality of fourth electrodes 54 may be arranged along the fourth direction D4. Corresponding to one fourth electrode 54, a set including the first partial region 15a, the fourth semiconductor region 14, and the fourth partial region 15d is provided. The plurality of sets may be arranged along the second direction D2.

The pitch (second pitch) of the plurality of fourth electrodes 54 in the second direction D2 may be longer than the pitch (first pitch) of the plurality of third electrodes 53 in the fourth direction D4.

As shown in FIGS. 1 and 3, the sixth semiconductor region 16 may further include a second semiconductor portion 16b. The fifth semiconductor region 15 may further include a sixth partial region 15f. The second semiconductor portion 16b is between the fourth semiconductor region 14 and the fifth partial region 15e in the second direction D2. The sixth partial region 15f is between the fourth semiconductor region 14 and the second semiconductor portion 16b in the second direction D2.

A part of the second semiconductor portion 16b is between the first electrode 51 and the fourth partial region 15d in the first direction D1. For example, another part of the second semiconductor portion 16b may be between the fourth electrode 54 and the fourth partial region 15d in the first direction D1.

The fourth partial region 15d is between the first electrode 51 and the first semiconductor region 11 in the first direction D1. In this example, a part of the fourth partial region 15d is between the fifth partial region 15e and the first semiconductor region 11 in the first direction D1.

At least a part of the second insulating member 42 is provided between the fourth electrode 54 and the second semiconductor portion 16b, and between the fourth electrode 54 and the sixth partial region 15f. For example, the first electrode 51 may be in contact with the fifth partial region 15e. For example, a part of the first electrode 51 may be in contact with the third partial region 15c and a part of the first semiconductor portion 16a at one first contact face 51F. For example, another part of the first electrode 51 may be in contact with the fifth partial region 15e and a part of the second semiconductor portion 16b at another first contact face 51F.

The semiconductor device 110 may further include a third insulating member 43. At least a part of the third insulating member 43 is between the third electrode 53 and the second electrode 52.

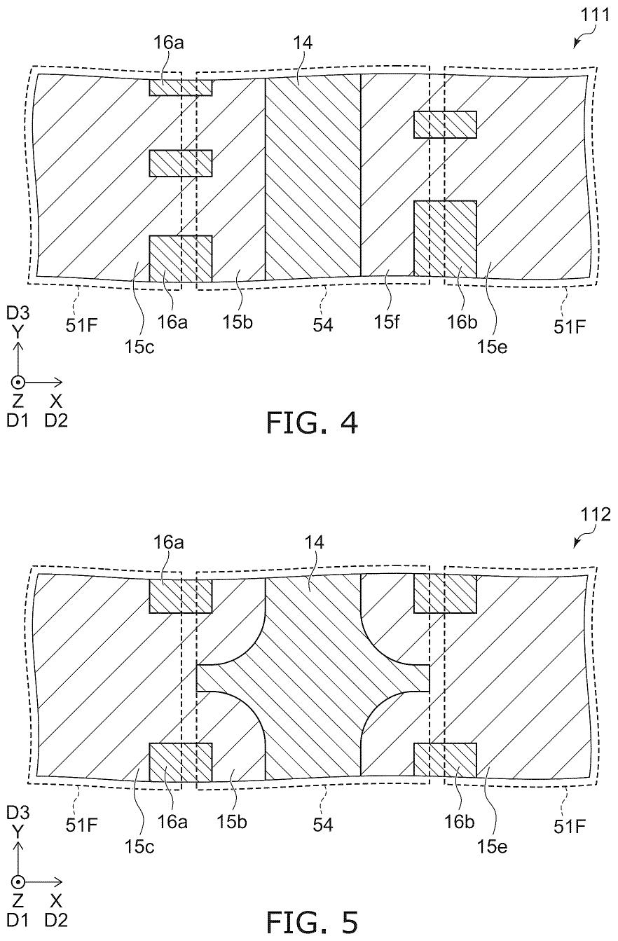

FIG. 4 is a schematic transparent plan view illustrating a semiconductor device according to the first embodiment.

As shown in FIG. 4, the semiconductor member 10M of a semiconductor device 111 according to the embodiment includes a plurality of first semiconductor portions 16a. A direction from one of the plurality of first semiconductor portions 16a to another one of the plurality of first semiconductor portions 16a is along a third direction D3 that crosses a plane including the first direction D1 and the second direction D2. The configuration of the semiconductor device 111 except for this may be the same as the configuration of the semiconductor device 110.

FIG. 5 is a schematic transmission plane view illustrating a semiconductor device according to the first embodiment.

As shown in FIG. 5, in a semiconductor device 112 according to the embodiment, a part of the fourth semiconductor region 14 is between one of the plurality of first semiconductor portions 16a and another one of the plurality of first semiconductor portions 16a in the third direction D3. The configuration of the semiconductor device 112 except for this may be the same as the configuration of the semiconductor device 111.

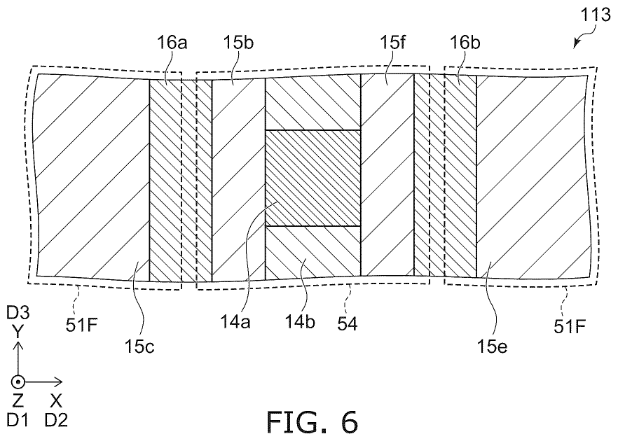

FIG. 6 is a schematic transmission plane view illustrating a semiconductor device according to the first embodiment.

As shown in FIG. 6, the fourth semiconductor region 14 of a semiconductor device 113 according to the embodiment further includes a first portion 14a and a second portion 14b. The first portion 14a is between a part of the second portion 14b and another part of the second portion 14b. The configuration of the semiconductor device 113 except for this may be the same as the configuration of the semiconductor device 110.

A first portion impurity concentration Cq1 of the first conductivity type in the first portion 14a is different from a second portion impurity concentration Cq2 of first conductivity type in the second portion 14b. For example, the first portion impurity concentration Cq1 is higher than the second portion impurity concentration Cq2.

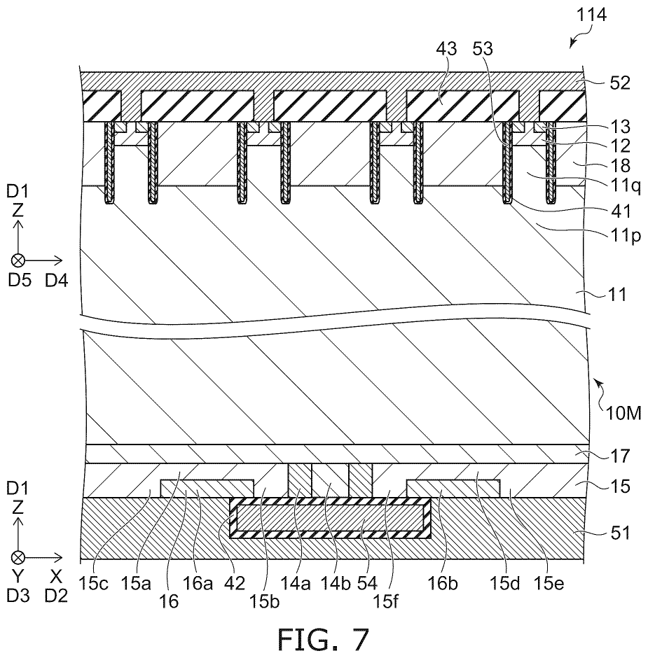

FIG. 7 is a schematic cross-sectional view illustrating a semiconductor device according to the first embodiment.

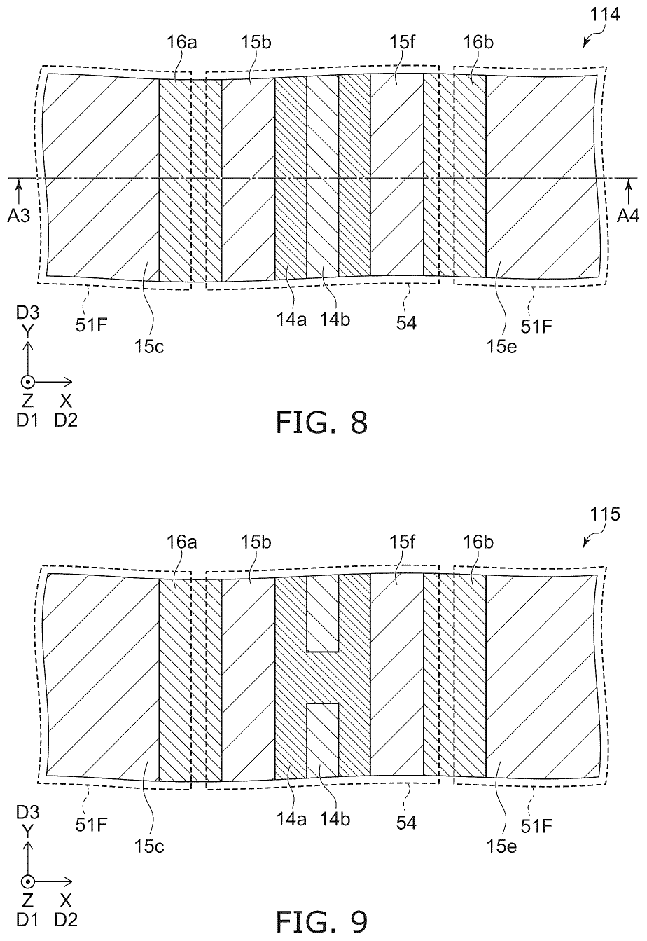

FIG. 8 is a schematic transparent plan view illustrating the semiconductor device according to the first embodiment.

FIG. 9 is a schematic transparent plan view illustrating the semiconductor device according to the first embodiment.

FIG. 7 corresponds to a cross-sectional view taken along the line A3-A4 in FIG. 8.

As shown in FIGS. 7 and 8, in a semiconductor device 114 according to the embodiment, the second portion 14b is between a part of the first portion 14a and another part of the first portion 14a in the second direction D2. The configuration of the semiconductor device 114 except for this may be the same as the configuration of the semiconductor device 110.

As shown in FIG. 9, in a semiconductor device 115 according to the embodiment, at least a part of the second portion 14b is between a part of the first portion 14a and another part of the first portion 14a in the second direction D2. A part of the first portion 14a is located between a part of the second portion 14b and another part of the second portion 14b in the third direction D3. The configuration of the semiconductor device 115 except for this may be the same as the configuration of the semiconductor device 114.

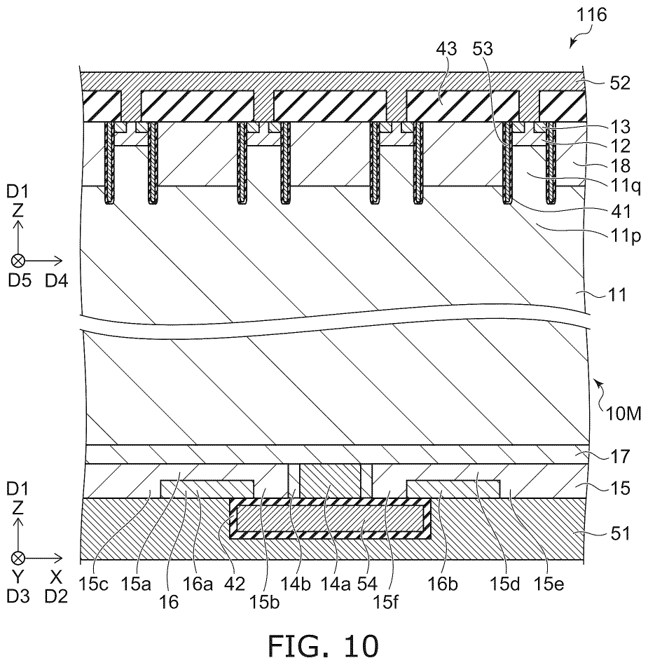

FIG. 10 is a schematic cross-sectional view illustrating a semiconductor device according to the first embodiment.

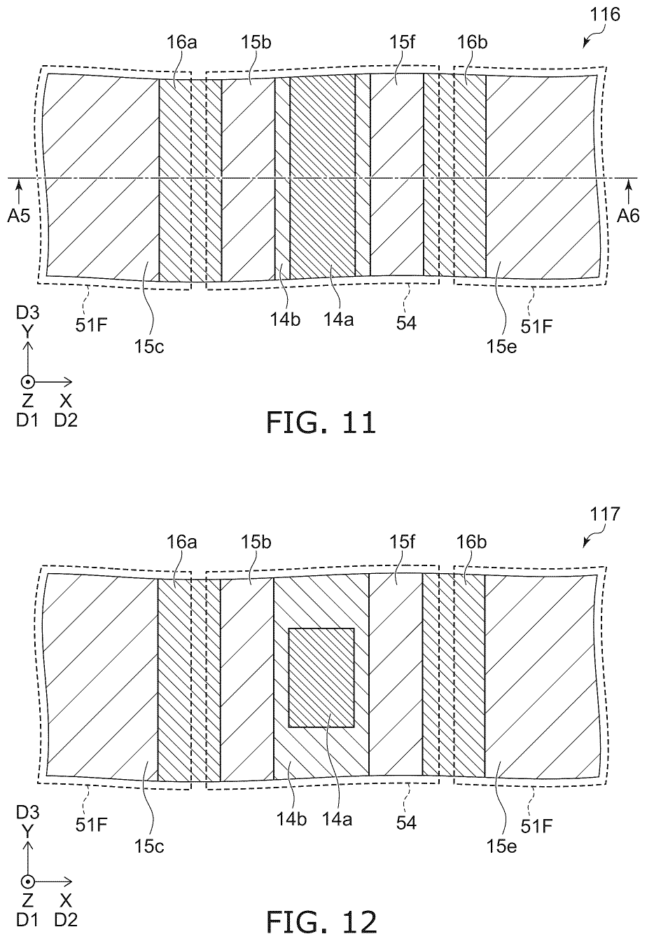

FIG. 11 is a schematic transparent plane view illustrating the semiconductor device according to the first embodiment.

FIG. 12 is a schematic transparent plane view illustrating the semiconductor device according to the first embodiment.

FIG. 10 corresponds to a cross-sectional view taken along the line A5-A6 in FIG. 11.

As shown in FIGS. 10 and 11, in a semiconductor device 116 according to the embodiment, the first portion 14a is between a part of the second portion 14b and another part of the second portion 14b in the second direction D2. The configuration of the semiconductor device 116 except for this may be the same as the configuration of the semiconductor device 110.

As shown in FIG. 12, in a semiconductor device 117 according to the embodiment, the second portion 14b is provided around the first portion 14a in a plane crossing the first direction D1. The configuration of the semiconductor device 114 except for this may be the same as the configuration of the semiconductor device 116.

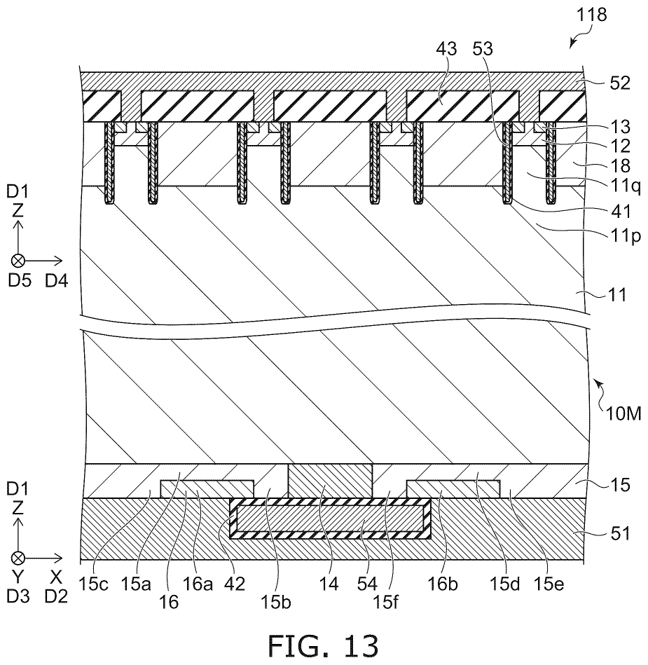

FIG. 13 is a schematic cross-sectional view illustrating a semiconductor device according to the first embodiment.

As shown in FIG. 13, in a semiconductor device 118 according to the embodiment, the seventh semiconductor region 17 is not provided. The configuration of the semiconductor device 118 except for this may be the same as the configuration of the semiconductor device 110.

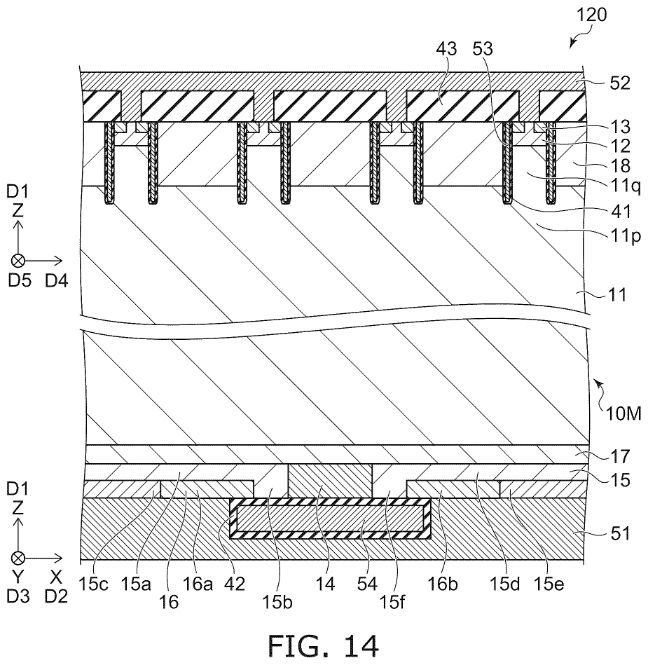

FIG. 14 is a schematic cross-sectional view illustrating a semiconductor device according to the second embodiment.

As shown in FIG. 14, in a semiconductor device 120 according to the embodiment, the impurity concentration of the second conductivity type in the third partial region 15c is higher than the impurity concentration of the second conductivity type in the first partial region 15a. The configuration of the semiconductor device 120 except for this may be the same as the configuration of the semiconductor device 110.

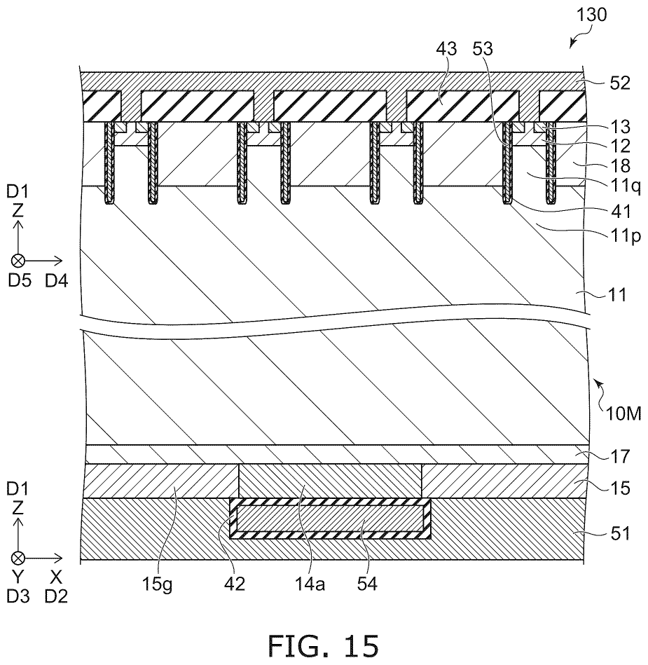

FIG. 15 is a schematic cross-sectional view illustrating a semiconductor device according to the second embodiment.

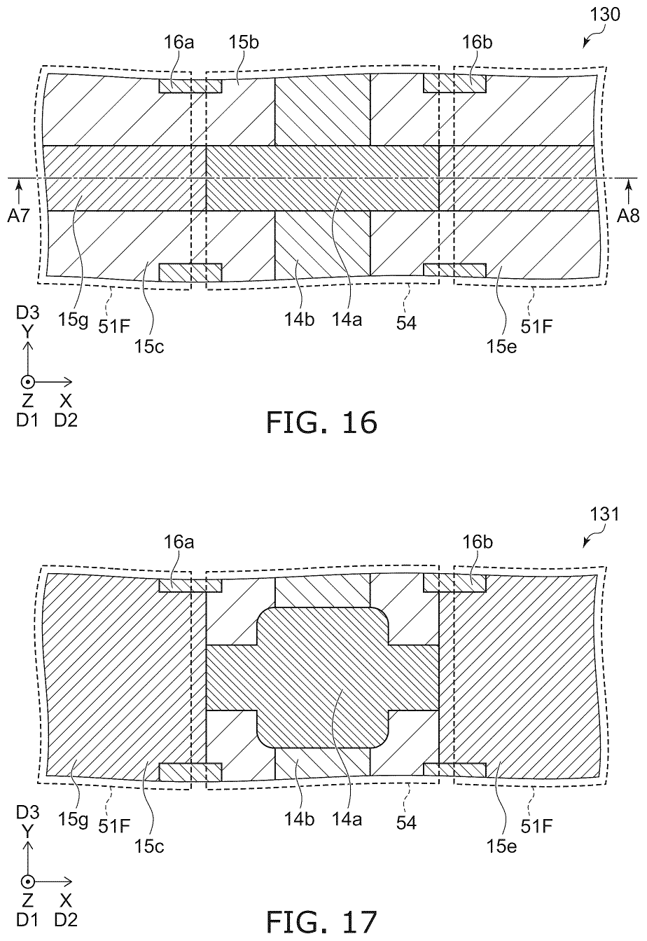

FIG. 16 is a schematic transparent plan view illustrating the semiconductor device according to the second embodiment.

FIG. 17 is a schematic transparent plan view illustrating a semiconductor device according to the second embodiment.

FIG. 15 corresponds to a cross-sectional view taken along the line A7-A8 in FIG. 16.

As shown in FIGS. 15 and 16, in a semiconductor device 130 according to the embodiment, the fifth semiconductor region 15 further includes a seventh partial region 15g. The fourth semiconductor region 14 further includes the first portion 14a and the second portion 14b. The configuration of the semiconductor device 130 except for this may be the same as the configuration of the semiconductor device 111.

The seventh partial region 15g is located between the first electrode 51 and the first semiconductor region 11 in the first direction D1. A direction from at least a part of the seventh partial region 15g to the first portion 14a of the fourth semiconductor region 14 is inclined with respect to a direction from the first semiconductor portion 16a to the first portion 14a.

The impurity concentration of the second conductivity type in the seventh partial region 15g is higher than the impurity concentration of the second conductivity type in the second partial region 15b.

In a semiconductor device 131 according to the embodiment of the example shown in FIG. 17, the impurity concentration of the second conductivity type in the third partial region 15c is higher than the impurity concentration of the second conductivity type in the second partial region 15b. The configuration of the semiconductor device 131 except for this may be similar the same as the configuration of the semiconductor device 130.

In the embodiment, at least one of the first electrode 51 or the second electrode 52 may include a metal. The metal may include at least one selected from the group consisting of Al, Ti, Ni, Au, Ag, and Cu. At least one of the third electrode 53 or the fourth electrode 54 may include polysilicon. The semiconductor member 10M may include silicon. The semiconductor member 10M may include a compound semiconductor. The compound semiconductor may include at least one selected from the group consisting of SiC, GaN, GaO, and GaAs.

In the embodiment, information on the shape of the semiconductor region is obtained, for example, from an electron microscope image. Information on the composition and element concentration is obtained, for example, from EDX (Energy Dispersive X-ray Spectroscopy) or SIMS (Secondary Ion Mass Spectrometry). Information on the composition may be obtained, for example, from reciprocal space mapping.

According to the embodiment, a semiconductor device is provided that can improve characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode;
a fourth electrode;
a semiconductor member;
a first insulating member; and
a second insulating member,
at least a part of the semiconductor member being between the first electrode and the second electrode in a first direction from the first electrode to the second electrode,
the semiconductor member including:
a first semiconductor region of a first conductivity type,
a second semiconductor region of a second conductivity type,
a third semiconductor region of the first conductivity type,
a fourth semiconductor region of the first conductivity type,
a fifth semiconductor region of the second conductivity type, and
a sixth semiconductor region of the first conductivity type,
the second electrode being electrically connected to the third semiconductor region,
at least a part of the second semiconductor region being between the first semiconductor region and the third semiconductor region,
at least a part of the first insulating member being between the third electrode and the first semiconductor region, between the third electrode and the second semiconductor region, and between the third electrode and the third semiconductor region,
the fifth semiconductor region including a first partial region, a second partial region, a third partial region, and a fourth partial region,
the fourth semiconductor region being between the second partial region and the fourth partial region in a second direction crossing the first direction,
the sixth semiconductor region including a first semiconductor portion,
the first semiconductor portion being between the third partial region and the fourth semiconductor region in the second direction,
the second partial region being between the first semiconductor portion and the fourth semiconductor region,
a part of the first semiconductor portion being between the first electrode and the first partial region in the first direction,
the fourth partial region being between the first electrode and the first semiconductor region in the first direction,
at least a part of the second insulating member being between the fourth electrode and the first semiconductor portion, between the fourth electrode and the second partial region, and between the fourth electrode and the fourth semiconductor region,
the first electrode being electrically connected to the fifth semiconductor region, and
a fourth impurity concentration of the first conductivity type in at least a part of the fourth semiconductor region being higher than a first impurity concentration of the first conductivity type in the first semiconductor region.

2. The semiconductor device according to claim 1, wherein
the fourth semiconductor region includes a first position and a second position,
the second position is between the fourth electrode and the first position in the first direction, and
a second position impurity concentration of the first conductivity type at the second position is lower than a first position impurity concentration of the first conductivity type at the first position.

3. The semiconductor device according to claim 2, wherein
the fourth semiconductor region further includes a third position,
the first position is between the second position and the third position in the first direction, and
a third position impurity concentration of the first conductivity type at the third position is lower than the first position impurity concentration at the first position.

4. The semiconductor device according to claim 3, wherein
the semiconductor member further includes a seventh semiconductor region,
at least a part of the seventh semiconductor region is between the fifth semiconductor region and the first semiconductor region and between the fourth semiconductor region and the first semiconductor region in the first direction,
the seventh semiconductor region includes a fourth position and a fifth position,
the fifth position is between the third position and the fourth position in the first direction,
a fifth position impurity concentration of the first conductivity type at the fifth position is lower than a fourth position impurity concentration of the first conductivity type at the fourth position.

5. The semiconductor device according to claim 4, wherein
the fourth position impurity concentration is equal to or greater than the first impurity concentration.

6. The semiconductor device according to claim 2, wherein
the first position impurity concentration is not less than 1×10¹⁴ cm⁻³ and less than 1.0×10²¹ cm⁻³.

7. The semiconductor device according to claim 5, wherein
the fourth position impurity concentration is not less than 1×10¹⁴ cm⁻³ and less than 1.0×10²¹ cm⁻³.

8. The semiconductor device according to claim 1, wherein
the semiconductor member further includes a seventh semiconductor region,
at least a part of the seventh semiconductor region is between the fifth semiconductor region and the first semiconductor region and between the fourth semiconductor region and the first semiconductor region in the first direction, and
a seventh impurity concentration of the first conductivity type in the seventh semiconductor region is higher than the first impurity concentration.

9. The semiconductor device according to claim 8, wherein
the first impurity concentration is not less than 1.0×10¹² cm−3 and less than 2.0×10¹⁴ cm⁻³, and
the fourth impurity concentration is not less than 1.0×10¹⁴ cm⁻³ and less than 1.0×10²¹ cm⁻³.

10. The semiconductor device according to claim 1, wherein
the fourth semiconductor region further includes a first portion and a second portion,
a first portion impurity concentration of the first conductivity type in the first portion is different from a second portion impurity concentration of the first conductivity type in the second portion, and
the first portion is between a part of the second portion and another part of the second portion.

11. The semiconductor device according to claim 10, wherein
at least a part of the first portion is between the part of the second portion and the other part of the second portion in the second direction.

12. The semiconductor device according to claim 10, wherein
at least a part of the first portion is between the part of the second portion and the other part of the second portion in a third direction, and
the third direction crosses a plane including the first direction and the second direction.

13. The semiconductor device according to claim 10, wherein
the first partial impurity concentration is higher than the second partial impurity concentration.

14. The semiconductor device according to claim 1, wherein
the fourth semiconductor region further includes a first portion and a second portion,
a first portion impurity concentration of the first conductivity type in the first portion is higher than a second portion impurity concentration of the first conductivity type in the second portion, and
the second portion is located around the first portion in a plane crossing the first direction.

15. The semiconductor device according to claim 1, wherein
the sixth semiconductor region further includes a second semiconductor portion,
the fifth semiconductor region further includes a fifth partial region and a sixth partial region,
the second semiconductor portion is between the fourth semiconductor region and the fifth partial region in the second direction,
the sixth partial region is between the fourth semiconductor region and the second semiconductor portion in the second direction,
a part of the second semiconductor portion is between the first electrode and the fourth partial region in the first direction,
another part of the second semiconductor portion is between the fourth electrode and the fourth partial region in the first direction, and
at least a part of the second insulating member is between the fourth electrode and the second semiconductor portion and between the fourth electrode and the sixth partial region.

16. The semiconductor device according to claim 1, wherein
the sixth semiconductor region is not provided between the first electrode and the fourth partial region in the first direction.

17. The semiconductor device according to claim 1, wherein
the sixth semiconductor region includes a plurality of the first semiconductor portions,
a direction from one of the plurality of the first semiconductor portions to another one of the plurality of the first semiconductor portions is along a third direction,
the third direction crosses a plane including the first direction and the second direction, and
a part of the fourth semiconductor region is between the one of the plurality of the first semiconductor portions and the other one of the plurality of the first semiconductor portions in the third direction.

18. The semiconductor device according to claim 1, wherein
an impurity concentration of the second conductivity type in the third partial region is higher than an impurity concentration of the second conductivity type in the first partial region.

19. The semiconductor device according to claim 13, wherein
the fifth semiconductor region further includes a seventh partial region,
at least a part of the seventh partial region is between the first electrode and the first semiconductor region in the first direction,
a direction from the at least a part of the seventh partial region to the first portion is inclined with respect to a direction from the first semiconductor portion to the first portion, and
an impurity concentration of the second conductivity type in the seventh partial region is higher than an impurity concentration of the second conductivity type in the second partial region.

20. The semiconductor device according to claim 19, wherein
an impurity concentration of the second conductivity type in the third partial region is higher than an impurity concentration of the second conductivity type in the second partial region.
